(19) United States
(12) Patent Application Publication
(10) Pub. No.: US 2023/0375634 A1
(43) Pub. Date: Nov. 23, 2023

(54) Device and Method for Detecting Deterioration

(71) Applicant: Nippon Telegraph and Telephone Corporation, Tokyo (JP)

(72) Inventors: Shota Oki, Tokyo (JP); Shingo Mineta, Tokyo (JP); Mamoru Mizunuma, Tokyo (JP); Soichi Oka, Tokyo (JP)

(21) Appl. No.: 18/246,960

(22) PCT Filed: Oct. 29, 2020
(86) PCT No.: PCT/JP2020/040585

§ 371 Date: Mar. 28, 2023

(51) Int. Cl. G01R 31/392; G01R 31/382

(52) U.S. Cl. CPC G01R 31/392; G01R 31/382

(57) ABSTRACT

Provided is a deterioration detection device including a battery including a positive electrode, a negative electrode, and a separator disposed between the positive electrode and the negative electrode. Furthermore, the deterioration detection device includes a container that covers and houses the battery and is to be embedded in a metal structure being a target of detecting a corrosion thinning state. Furthermore, the deterioration detection device includes a detection unit that detects a current or a voltage output from the battery in an electromotive state and outputs that the metal structure is corroded and thinned.

### CROSS-REFERENCE TO RELATED APPLICATIONS

This application is a national phase entry of PCT Application No. PCT/JP2020/040585, filed on Oct. 29, 2020, which application is hereby incorporated herein by reference.

### TECHNICAL FIELD

The present invention relates to a deterioration detection device and a deterioration detection method for detection of deterioration of a metal structure.

### BACKGROUND

The infrastructure facilities supporting our lives have been developed in large quantities rapidly in approximately 20 years after the high economic growth period. Therefore, in 2030, facilities constructed 50 or more years ago will account for a half or more of the entire facilities, and there is a concern that aging facilities projected in the future will increase more and more. Furthermore, the working population of skilled engineers, which is essential for reliably maintaining the infrastructure facilities, is rapidly decreasing, and the feasible maintenance quantity is steadily decreasing. For these reasons, it is concerned that continuous maintenance of the infrastructure facilities will become difficult. In this situation, if the fact of deterioration of a facility can be found out when the facility deteriorates to a certain threshold, the target facility can be immediately treated, and thus, the safety and the security of the facility can be ensured for a long period of time.

In order to maintain the safety and the security of metal facilities, it is important to grasp the deterioration states of the facilities and to maintain the facilities appropriately according to the grasped deterioration states. For grasp of the deterioration state of a facility, a visual inspection is mainly performed currently. The visual confirmation enables accurate awareness of the actual state and acquisition of reliable knowledge. However, in a structure such as a concrete structure, a minute crack that is visible or invisible contributes to progress of deterioration, and therefore an inspection by a skilled engineer is essential in visual confirmation so as not to overlook the sign of deterioration.

### SUMMARY

### Technical Problem

However, as described above, the working population of skilled engineers has been on a decreasing trend in recent years, and therefore it is considered that inspections of large quantities of deterioration facilities will become difficult in the future. Even if the current level of a visual inspection is continued, the inspection of each of the facilities installed in large quantities throughout the country is not realistic because the cost such as a labor cost is increased.

In addition, a visual inspection itself is impossible for facilities existing in invisible areas. Representative examples of the area where a visual inspection is impossible include areas in the ground. Examples of the facility buried in the ground include water and gas pipelines, electric power cable ducts, underground tanks, overpack materials for spent nuclear fuel, steel pipe columns, and guy anchors, and metal materials including steel materials are very often used. In the metal materials buried in the ground, deterioration progresses due to soil corrosion.

Soil corrosion is a phenomenon in which a metal material in contact with soil rusts at the interface and decreases in thickness of the base material. If the thickness of the base material is decreased due to soil corrosion, for example, stress or the like applied to the facility cannot be supported because the design proof stress to be originally secured by the base material is unreached, and there is a concern about occurrence of an accident in which the facility collapses. Furthermore, if the thickness of the base material used in a pipeline or an overpack material is decreased and a hole is generated in a part, the internal gas, water, radioactive ray from spent nuclear fuel, or the like flows out, and the flow out may lead to a serious accident. For facilities in invisible areas where an inspection is impossible, a diagnosis method has also been studied using ultrasonic waves or the like. However, such a diagnosis method is difficult to apply, for example, to a complicated structure such as a guy anchor.

Management of facilities as described above currently employs time-based maintenance in which older targets are renewed among facilities that have passed a certain number of years from their construction. However, the corrosion rate greatly depends on the installation environment, and therefore even if facilities that have passed the same number of years are compared, some targets have not corroded at all and can be used for further several decades, and some targets have corroded at an abnormal rate and are to be renewed as soon as possible. In the time-based maintenance, it is difficult to realize both the economic efficiency of renewal and the safety of facilities.

Embodiments of the present invention have been made to solve the above problems, and an object of embodiments of the present invention is to enable detection of deterioration of a metal structure that cannot be visually inspected, such as a metal structure buried in the soil.

### Solution to Problem

The deterioration detection device according to embodiments of the present invention includes a battery including a positive electrode, a negative electrode, and a separator disposed between the positive electrode and the negative electrode and includes a container that covers and houses the battery and is to be embedded in a metal structure being a target of detecting a corrosion thinning state, wherein the separator swells by containing moisture to connect the positive electrode and the negative electrode to bring the battery into an electromotive state, the container includes a porous body including an insulating material, and water can penetrate into the container.

The deterioration detection method according to embodiments of the present invention includes: a first step of embedding a deterioration detection device, in a metal structure being a target of detecting a corrosion thinning state, the deterioration detection device including a battery including a positive electrode, a negative electrode, and a separator disposed between the positive electrode and the negative electrode and including a container that covers and houses the battery; a second step of detecting a current or a voltage output from the battery; and a third step of outputting that the metal structure is corroded and thinned when the current or the voltage output from the battery is detected, wherein the separator swells by containing moisture to connect the positive electrode and the negative electrode to bring the battery into an electromotive state, the container includes a porous body including an insulating material, and water can penetrate into the container.

### Advantageous Effects of Embodiments of Invention

As described above, according to embodiments of the present invention, the container houses the battery including the positive electrode and the negative electrode disposed with the separator, interposed therebetween, that swells by containing moisture, and the container is embedded in the metal structure being a target of detecting, and therefore it is possible to detect deterioration of a metal structure that cannot be visually inspected, such as a metal structure buried in the soil.

### BRIEF DESCRIPTION OF THE DRAWINGS

FIG. 1 is a configuration diagram illustrating a configuration of a deterioration detection device according to an embodiment of the present invention.

FIG. 2 is a perspective view illustrating a partial configuration of a deterioration detection device according to an embodiment of the present invention.

FIG. 3 is a sectional view illustrating a configuration of another deterioration detection device according to an embodiment of the present invention.

FIG. 4 is a flowchart for explaining a deterioration detection method according to an embodiment of the present invention.

### DETAILED DESCRIPTION OF ILLUSTRATIVE EMBODIMENTS

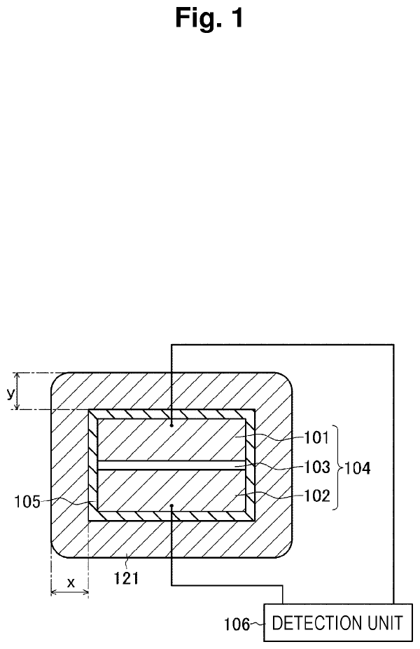

Hereinafter, a deterioration detection device according to an embodiment of the present invention will be described with reference to FIG. 1. In FIG. 1, a part of the device is shown in cross section. First, the deterioration detection device includes a battery 104 including a positive electrode 101, a negative electrode 102, and a separator 103 disposed between the positive electrode 101 and the negative electrode 102. Furthermore, the deterioration detection device includes a container 105 that covers and houses the battery 104 and is to be embedded in a metal structure 121 being a target of detecting a corrosion thinning state. Furthermore, the deterioration detection device includes a detection unit 106 that detects a current or a voltage output from the battery 104 in an electromotive state and outputs that the metal structure 121 is corroded and thinned.

The positive electrode 101 and the negative electrode 102 include metals that have a potential difference and thus can form a battery. The positive electrode 101 can include, for example, copper, and the negative electrode 102 can include, for example, zinc. In this case, the battery 104 has an electromotive force of 1.1 V in an electromotive state, and if the battery 104 is in the electromotive state described below, a sufficient current for operation of the detection unit 106 can be obtained. The positive electrode 101 and the negative electrode 102 are not limited as long as they are combined with each other so that an electromotive force is obtained to form a battery. The electromotive force is desirably about 1 V or more.

Furthermore, the separator 103 swells by containing moisture to connect the positive electrode 101 and the negative electrode 102 to bring the battery 104 into an electromotive state. The separator 103 includes, for example, a polymer in a powder form, and can include a gel body that swells by containing moisture to form a gel. The gel body is a swollen polymer in which a three-dimensional network structure is formed using a crosslinking agent and a solution is included in the network, and is referred to as gel or polymer gel. The composition of the gel body is almost liquid while the gel body exhibits almost the same mechanical properties as a solid.

Examples of the material of the separator 103 described above include polyacrylic acid and polyhydroxyethyl methacrylate. Gels including these materials expand to 103 times in volume in their state changes from a dry state to a wet state. In consideration of this swelling rate, the amount of the gel used in the separator 103 is designed so that the positive electrode 101 and the negative electrode 102 are in an electromotive state with the separator 103 interposed therebetween even when a small amount of water enters.

Furthermore, it is possible to devise so that the positive electrode 101 and the negative electrode 102 are reliably in an electromotive state with the moisture-containing separator 103 interposed therebetween. For example, a capsule housing an ionic powder such as a salt is dispersed in the separator 103, and the capsule dissolves because the separator 103 contains water, and thus the separator 103 swells with water in which the electrolyte is dissolved. In this state, electron transfer between the positive electrode 101 and the negative electrode 102 each in contact with the separator 103 is facilitated to help formation of a battery. As the capsule, a medical hard capsule can be applied that is prepared using gelatin, hydroxypropylmethyl cellulose, or the like as a raw material. The separator 103 is preferably maintained in a dry state using a drying material or the like in order to prevent swelling due to humidity or to prevent breaking of the capsule housing a salt.

In a case where the gel has too high a salt concentration when the gel swells by containing moisture, the gel may be not sufficiently swollen if the gel is a general gel. When the salt concentration is adjusted to be high, as the material of the separator 103, a polyethylene oxide (PEO) gel can be used that exhibits a swelling rate about as high as or higher than that of pure water in a solution containing an alkali metal salt (LiCl) and an alkaline earth metal salt (MgCl₂).

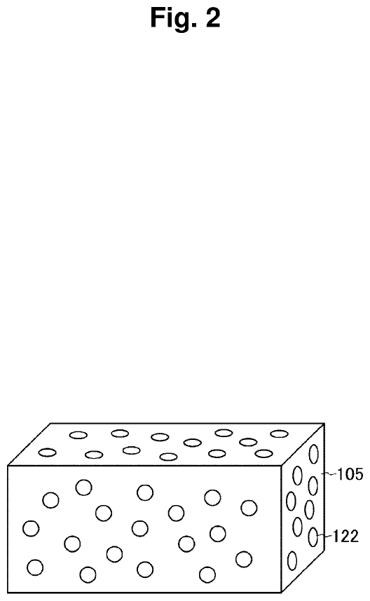

The container 105 includes an insulating material. As illustrated in FIG. 2, the container 105 includes a porous body having a plurality of holes 122, and water can penetrate into the container 105 from the outside of the container 105. The penetration (entering) of water into the container 105 may be prevented by surface tension of water. Therefore, the holes 122 having too small a diameter are not preferable. The surface tension of water also depends on the material used in the container 105, and if a material having a large contact angle with a droplet, that is, a material that repels water is used, the holes are difficult to pass through due to the surface tension. Therefore, the container 105 preferably includes a material that is less likely to repel (does not repel) water. The container 105 can include, for example, glass or plastic.

The container 105 including a metal is not preferable because contact between the metal and the metal structure 121 causes galvanic corrosion and deterioration may progress from the inside of the metal structure 121. Furthermore, the container 105 including a metal is not preferable because contact between the metal and the positive electrode 101 or the negative electrode 102 causes an electromotive state even when the separator 103 is not swollen.

The detection unit 106 includes, for example, a well-known personal computer and an ammeter, measures the current generated from the battery 104, and outputs that the metal structure 121 is corroded and thinned by the operation of the personal computer when the current equal to or larger than a set threshold is measured. The personal computer includes a central processing unit (CPU), a main storage device, an external storage device, a network connection device, and the like, and implements the above-described functions (method) by operation of the CPU with a program developed in the storage device (execution of the program).

The output of the state that the metal structure 121 is corroded and thinned can be performed, for example, by displaying an alert indicating that the metal structure 121 has reached its end of life on a display unit included in the personal computer. This display can be freely customized so that the user can visually recognize it easily. Furthermore, wireless notification from the personal computer to a portable terminal device enables setting such that the state of the metal structure 121 can be monitored at any time.

The metal structure 121 is a metal structure serving as a metal facility, and may include any metal material. In order to incorporate (embed) the container 105 in the metal structure 121, the container 105, the positive electrode 101, the negative electrode 102, and the separator 103 are sized so that the above-described state is possible. Furthermore, since the container 105 is incorporated in the metal structure 121, it is preferable to sufficiently pay attention to each design so that the set proof stress required for the metal structure 121 (metal conceptual object) is not unreached.

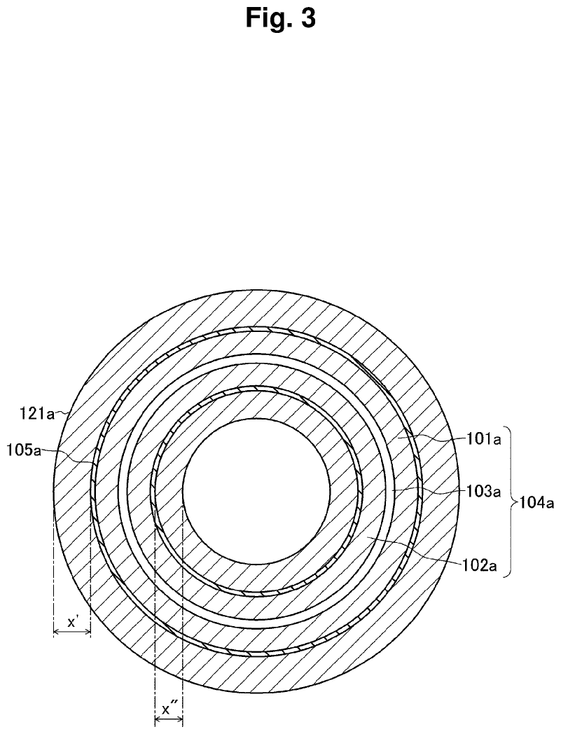

Here, as illustrated in FIG. 3, in a case where a metal structure 121a is a pipe (gas pipe, water pipe) or the like and is annular, a battery 104a can be a battery in which a positive electrode 101a, a negative electrode 102a, and a separator 103a are each annular. A cylindrical container 105a extending in the circumferential direction of the pipe wall is embedded in the pipe wall of the annular metal structure 121a, and the positive electrode 101a, the negative electrode 102a, and the separator 103a that are each annular can be housed in the container 105a.

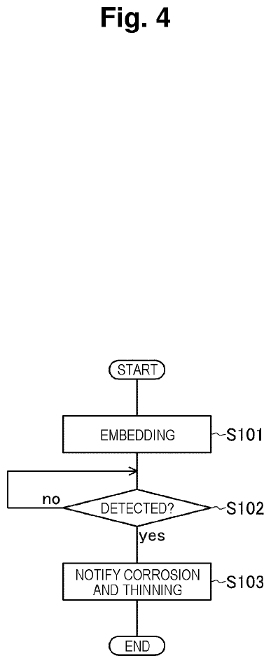

Next, a deterioration detection method in which the deterioration detection device according to the above-described embodiment is used will be described with reference to FIG. 4.

First, in a first step S101, a deterioration detection device that includes a battery 104 including a positive electrode 101, a negative electrode 102, and a separator 103 disposed between the positive electrode 101 and the negative electrode 102 and includes a container 105 that covers and houses the battery 104 is embedded in a metal structure 121 being a target of detecting a corrosion thinning state.

Next, in a second step S102, the current or the voltage output from the battery 104 is detected by a detection unit 106. For example, if the detection unit 106 detects the current output from the battery 104 (yes in the second step S102), the detection unit 106 outputs that the metal structure 121 is corroded and thinned, in a third step S103.

For example, if corrosion and thinning of the metal structure 121 reaches the container 105, water can enter the container 105 from the outside. Here, if water reaches the container 105, the water penetrates into the container 105 that is a porous body, and if the penetrating water reaches the separator 103, the separator 103 swells by containing moisture to connect the positive electrode 101 and the negative electrode 102 to bring the battery 104 into an electromotive state. As a result, the detection unit 106 detects the current output from the battery 104 in an electromotive state and outputs that the metal structure 121 is corroded and thinned.

Here, if corrosion and thinning of the metal structure 121 reaches the container 105, the detection unit 106 outputs that the metal structure 121 is corroded and thinned, and the time interval from when the corrosion and the thinning reaches the container 105 to when the state of the corrosion and the thinning is output is the time when water reaches the separator 103 and the battery 104 is brought into an electromotive state. Therefore, if water reaches the separator 103 more quickly, the time interval described above can be shortened. For example, if the positive electrode 101 and the negative electrode 102 are a porous body, the water that has entered the inside of the container 105 can pass through the porous medium of the positive electrode 101 or the negative electrode 102 and reach the separator 103 more quickly. As the porous electrode, for example, a general electrode used in a fuel cell or the like can be used.

Hereinafter, deterioration of the metal structure 121 will be described. The metal structure 121 deteriorates due to corrosion in a natural environment. The deterioration of the metal structure 121 is based on an oxidation-reduction reaction, and an oxidation reaction (cathode reaction) in which a metal is ionized and a reduction reaction (anode reaction) in which dissolved oxygen or the like receives electrons proceed (Literature 1, Literature 2). In a case where the metal structure 121 is general iron, the corrosion reactions are represented by “Fe→Fe²⁺+2e⁻ . . . (1)” and “O₂+2H₂O+4e⁻→4OH⁻ . . . (2)”.

Deterioration of the metal due to corrosion results from a decrease in the thickness of the iron base due to ionization of iron represented by the formula (1). Therefore, the decrease in the thickness of the base material with which a facility reaches its end of life depends on the metal structure. For example, in a lower guy anchor buried to support a utility pole, a decrease in the thickness of the base material causes a decrease in the proof stress required for supporting the linear stress from the utility pole. Therefore, the proof stress decreases with a decrease in the thickness of the lower guy anchor, and the lower guy anchor reaches its end of life when corrosion deterioration progresses until the proof stress required for safe use of the utility pole is unreached. Furthermore, in a facility such as a water pipe or a gas pipe, the thickness of the pipe wall decreases due to corrosion, and the facility reaches its end of life when a hole is generated even in a part.

As described above, the concept of the end of life varies depending on the facility, but it is found that the end of life is commonly caused by a decrease in the thickness of the metal portion by a certain amount (to a certain depth) due to corrosion. As described above, if the thickness of the metal structure 121 between the surface of the metal structure 121 and the embedded container 105 is decreased, water can enter the container 105 from the outside. As a result, the battery 104 is brought into an electromotive state, and the detection unit 106 outputs a notification that the metal structure 121 is corroded and thinned. If corrosion causes decreases in the thicknesses of the metal structure 121 up to the container 105 that are represented by x and y in FIG. 1 and decreases in the thicknesses of the metal structure 121a up to the container 105a that are represented by x′ and x″ in FIG. 3, a notification of the corrosion and the thinning is output to notify the end of life of the facility to the user.

The values of x, y, x′, and x″ described above can be set to any values according to the facility. For example, in the case of a facility in which the metal structure 121 is buried in the soil, the entire surface of the metal structure 121 is surrounded by the soil, and the entire surface is exposed to the same environment. In such a case, the values can be set to satisfy x=y.

In the case of the metal structure 121a described with reference to FIG. 3, the metal structure 121a is often in a situation where the outer circumferential surface and the inner circumferential surface of the metal structure 121a are exposed to different environments. For example, in the case of a gas pipe, the outer circumferential surface is exposed to the soil or the air, and the inner circumferential surface is exposed to the gas to be transported. In the case of a water pipe, the outer circumferential surface is exposed to the soil or the air, and the inner circumferential surface is exposed to the water to be transported. Therefore, x′ and x″ can be designed to values suitable for each environment.

The position where the container 105 is embedded in the metal structure 121 can be designed and determined in any manner by the user. As described above, if the thickness between the surface of the metal structure 121 and the container 105 is decreased, the detection unit 106 transmits a notification indicating the end of life of the facility.

As described above, according to embodiments of the present invention, the container houses the battery including the positive electrode and the negative electrode disposed with the separator, interposed therebetween, that swells by containing moisture, and the container is embedded in the metal structure being a target of detecting, and therefore it is possible to detect deterioration of a metal structure that cannot be visually inspected, such as a metal structure buried in the soil.

Note that the present invention is not limited to the embodiments described above, and it is obvious that many modifications and combinations can be implemented by a person having ordinary knowledge in the art within the technical idea of the present invention.

### REFERENCE LITERATURE

[Literature 1] Y. Wan et al., “Corrosion Behaviors of Q235 Steel in Indoor Soil”, International Journal of Electrochemical Science, vol. 8, pp. 12531-12542, 2013.
[Literature 2] M. Barbalat et al., “Electrochemical study of the corrosion rate of carbon steel in soil: Evolution with time and determination of residual corrosion rates under cathodic protection”, Corrosion Science, vol. 55, pp. 246-253, 2012.

### REFERENCE SIGNS LIST

101 Positive electrode
102 Negative electrode
103 Separator
104 Battery
105 Container
106 Detection unit
121 Metal structure.

1-4. (canceled)

5. A deterioration detection device comprising:
a battery including a positive electrode, a negative electrode, and a separator disposed between the positive electrode and the negative electrode; and
a container that houses the battery, the container being embedded in a metal structure, the metal structure being a target of detecting a corrosion thinning state,
wherein the separator is configured to swell by containing moisture to connect the positive electrode and the negative electrode to bring the battery into an electromotive state,
wherein the container includes a porous body including an insulating material, and water can penetrate into the container.

6. The deterioration detection device according to claim 5, wherein:
the metal structure is annular; and
each of the positive electrode, the negative electrode, and the separator is annular.

7. The deterioration detection device according to claim 5, further comprising:
a detector configured to detect a current or a voltage output from the battery in an electromotive state and output an indication that the metal structure is corroded and thinned in response to detecting the current or the voltage output from the battery.

8. The deterioration detection device according to claim 6, further comprising:
a detector configured to detect a current or a voltage output from the battery in an electromotive state and output an indication that the metal structure is corroded and thinned in response to detecting the current or the voltage output from the battery.

9. The deterioration detection device according to claim 5, wherein the positive electrode comprises copper, and wherein the negative electrode comprises zinc.

10. The deterioration detection device according to claim 5, wherein the separator is a polymer material.

11. The deterioration detection device according to claim 10, wherein the polymer material is polyacrylic acid or polyhydroxyethyl methacrylate.

12. A deterioration detection method comprising:
a first step of embedding a deterioration detection device in a metal structure, the deterioration detection device being configured to detect a corrosion thinning state in the metal structure, the deterioration detection device including a battery including a positive electrode, a negative electrode, and a separator disposed between the positive electrode and the negative electrode, the deterioration detection device further including a container housing the battery;
a second step of detecting a current or a voltage output from the battery; and
a third step of outputting an indication that the metal structure is corroded in response to detecting the current or the voltage output from the battery,
wherein the separator swells by containing moisture to connect the positive electrode and the negative electrode to bring the battery into an electromotive state, and
wherein the container includes a porous body including an insulating material, and water can penetrate into the container.

13. The deterioration detection method according to claim 12, wherein:
the metal structure is annular; and
each of the positive electrode, the negative electrode, and the separator is annular.

14. The deterioration detection method according to claim 12, wherein the positive electrode comprises copper, and wherein the negative electrode comprises zinc.

15. The deterioration detection method according to claim 12, wherein the separator is a polymer material.

16. The deterioration detection method according to claim 15, wherein the polymer material is polyacrylic acid or polyhydroxyethyl methacrylate.
